(19) United States
(12) Patent Application Publication
(10) Pub. No.: US 2010/0148262 A1
(43) Pub. Date: Jun. 17, 2010

(54) Resistors and Methods of Manufacture Thereof

(76) Inventors: Knut Stahrenberg, Wappingers Falls, NY (US); Karl-Heinz Bach, Grobenzell (DE); Manfred Eller, Wappingers Falls, NY (US); Roland Hampp, Bad Abbach (DE); Jin-Ping Han, Fishkill, NY (US); O Sung Kwon, Wappingers Falls, NY (US)

Correspondence Address: SLATER & MATSIL LLP, 17950 PRESTON ROAD, SUITE 1000, DALLAS, TX, 75252, US

(21) Appl. No.: 12/336,702

(22) Filed: Dec. 17, 2008

(51) Int. Cl. H01L 29/772; H01L 21/02

(52) U.S. Cl. 257/350; 438/238; 257/E29.242; 257/E21.002

(57) ABSTRACT

Resistors, semiconductor devices, and methods of manufacture thereof are disclosed. In one embodiment, a method of fabricating a resistor includes forming a semiconductive material over a workpiece, and patterning at least the semiconductive material, forming a gate of a transistor in a first region of the workpiece and forming a resistor in a second region of the workpiece. At least one substance is implanted into the semiconductive material of the gate of the transistor or the resistor so that the semiconductive material is different for the gate of the transistor and the resistor.

### TECHNICAL FIELD

The present invention relates generally to the fabrication of semiconductor devices, and more particularly to the fabrication of resistors in integrated circuits.

### BACKGROUND

Semiconductor devices are used in a variety of electronic applications, such as personal computers, cell phones, digital cameras, and other electronic equipment, as examples. Semiconductor devices are typically fabricated by sequentially depositing insulating or dielectric layers, conductive layers, and semiconductive layers of material over a semiconductor substrate, and patterning the various layers using lithography to form circuit components and elements thereon.

Resistors are elements that are used in semiconductor devices in many applications. A resistor is a two-terminal electronic component designed to oppose an electric current by producing a voltage drop between the two terminals of the resistor in proportion to the current. The resistance (R) of a resistor is equal to the voltage drop (V) across the resistor divided by the current (I) through the resistor, in accordance with Ohm's law (V=IR, or R=V/I). Resistors are used as part of electronic circuits and can be formed in integrated circuits and semiconductor devices. Resistors are used in applications such as electronic filters, analog-to-digital converters, memory devices, control applications, and many other types of semiconductor device applications. Rather large resistors with high resistance values are often required in radio frequency (RF), analog, and mixed signal devices, as examples.

Transistors are elements that are also used frequently in semiconductor device applications. In the past, gate dielectric materials of transistors in semiconductor devices typically comprised silicon dioxide, which has a dielectric constant or k value of about 3.9. Gate materials of transistors typically comprised polysilicon. However, in some smaller and more advanced semiconductor technologies, such as a 32 nm technology node, as an example, the use of gate dielectric materials comprising silicon oxynitride and other high k dielectric materials such as hafnium-based dielectric materials having a dielectric constant (k) of greater than about 3.9 have begun to be a trend. Gate materials comprising metals have also begun to be used for transistors in semiconductor devices.

In some transistor applications, it is desirable to manufacture resistors from the material layers that transistor gates elsewhere on the chip are manufactured from. However, for some transistors that have a high k gate dielectric material and that include a metal layer in the gate stack, for example, the resistance of resistors manufactured from the same gate stack as the transistors is too low for some applications, particularly RF applications.

Thus, what are needed in the art are improved methods of fabricating resistors in semiconductor devices and structures thereof.

### SUMMARY OF THE INVENTION

Technical advantages are generally achieved by preferred embodiments of the present invention, which provide novel methods of manufacturing resistors and semiconductor devices, and structures thereof.

In accordance with one embodiment, a method of fabricating a resistor includes forming a semiconductive material over a workpiece, and patterning at least the semiconductive material, forming a gate of a transistor in a first region of the workpiece and forming a resistor in a second region of the workpiece. At least one substance is implanted into the semiconductive material of the gate of the transistor or the resistor so that the semiconductive material is different for the gate of the transistor and the resistor.

The foregoing has outlined rather broadly the features and technical advantages of embodiments of the present invention in order that the detailed description of the invention that follows may be better understood. Additional features and advantages of embodiments of the invention will be described hereinafter, which form the subject of the claims of the invention. It should be appreciated by those skilled in the art that the conception and specific embodiments disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is a cross-sectional view of a prior art semiconductor device including a resistor formed from the same gate stack materials as a transistor;

FIG. 2 shows a cross-sectional view of another prior art semiconductor device, wherein a metal layer of the gate stack materials is removed from within the resistor;

FIG. 3 is a graph illustrating some exemplary resistance values of the resistors shown in FIGS. 1 and 2;

FIG. 4 is a cross-sectional view of a semiconductor device in accordance with an embodiment of the present invention, wherein doping levels of a semiconductive material of a resistor are selected to increase the resistance value of the resistor;

FIGS. 5 through 7 show cross-sectional views of a method of manufacturing a semiconductor device in accordance with an embodiment of the present invention;

FIG. 8 illustrates a method of forming a resistor in accordance with an embodiment of the present invention;

FIGS. 9 and 10 illustrate a method of forming a resistor in accordance with another embodiment of the present invention;

FIGS. 11 and 12 illustrate a method of forming a resistor in accordance with yet another embodiment of the present invention;

FIG. 13 shows a cross-sectional view of a resistor in accordance with an embodiment after contacts have been coupled to each end of the resistor; and

FIGS. 14 and 15 show top views of resistors in accordance with embodiments of the present invention.

Corresponding numerals and symbols in the different figures generally refer to corresponding parts unless otherwise indicated. The figures are drawn to clearly illustrate the relevant aspects of the preferred embodiments and are not necessarily drawn to scale.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

Resistors are circuit elements that are required in many semiconductor devices applications. It is desirable to manufacture resistors in semiconductor devices without requiring additional manufacturing processing steps. In some applications, it may be desirable to manufacture resistors from the same polysilicon layer that transistor gates are manufactured from.

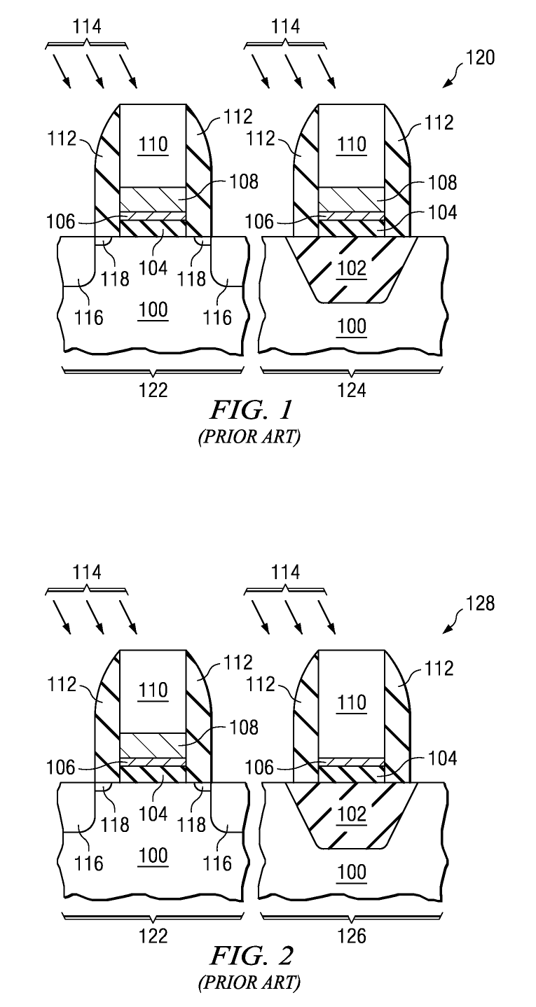

For example, FIG. 1 shows a prior art semiconductor device 120 wherein a transistor is formed in a transistor region 122 and a resistor is formed in a resistor region 124. The semiconductor device 120 includes a workpiece 100 comprising a silicon substrate and a shallow trench isolation (STI) region 102 formed in the workpiece 100 in the resistor region 124. The transistor in the transistor region 122 includes a gate stack comprising a gate dielectric 104, a cap layer 106, a metal layer 108, and a layer of polysilicon 110 that is doped with a P+ material using an implantation process 114. The gate dielectric 104 may comprise a high dielectric constant (k) material and the metal layer 108 may comprise TiN, for example. The transistor in the transistor region 122 also includes source and drain regions 116/118 formed within the workpiece 100 near sidewall spacers 112 formed over sidewalls of the gate stack 104, 106, 108, and 110.

In some designs, a resistor may be formed in the resistor region 124 over the STI region 102. The resistor is fabricated from the same material layers 104, 106, 108, and 110 of the gate stack of the transistor in the transistor region 122. However, the resistance of a resistor comprising such a structure may have a resistance that is too low for a polysilicon resistor device in some applications, due to the presence of the metal layer 108. For example, in some RF designs, high precision high and medium ohmic resistors are required. In some technology nodes, such as 32 nm as an example, a P+ doped polysilicon 110 resistor in resistor region 124 may have a resistance that is dominated by the low resistance of the metal layer 108, resulting in a sheet resistance of about 150 Ohms/square, which is too low for the requirements of some RF designs.

In some prior art processes, an additional lithography mask and lithography process may be used to remove the metal layer 108 of the gate stack materials in the resistor region 124, as shown in FIG. 2 in a cross-sectional view. Removing the metal layer 108 from the resistor results in a resistor with a higher resistance value. However, the additional masking level and lithography process add to the complexity and expense of the fabrication process for the semiconductor device 120.

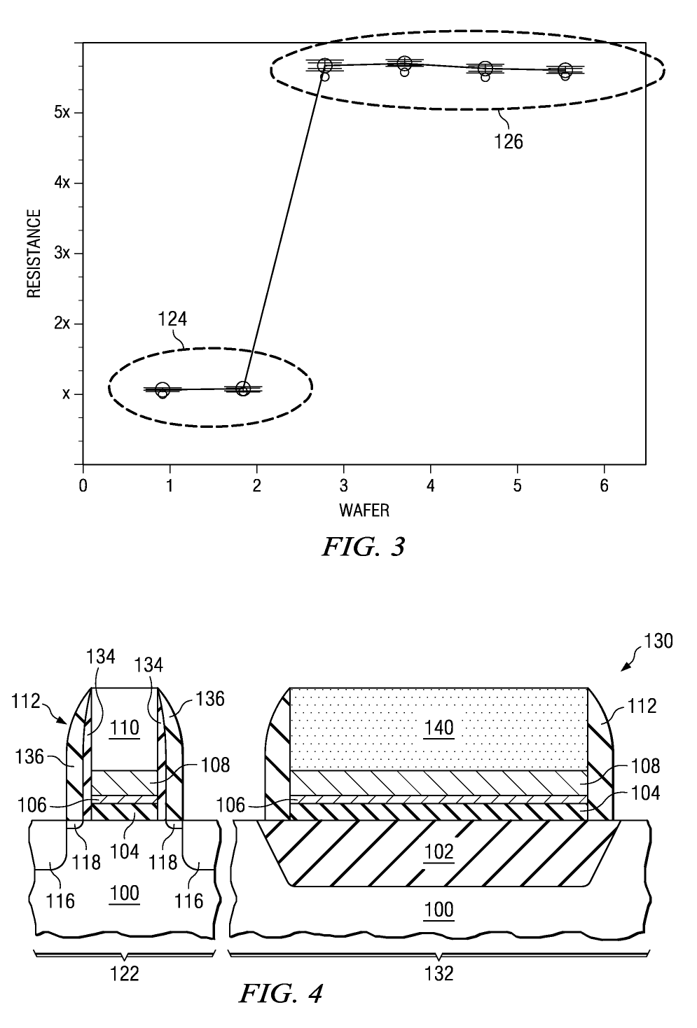

FIG. 3 is a graph illustrating some exemplary resistance values of the resistors shown in FIGS. 1 and 2. Various wafers, shown on the x axis, were tested to determine the resistance, shown on the y axis, of resistors formed. The resistance of resistors shown in resistor region 124 in FIG. 1 is shown at 124 in FIG. 3, and the resistance of resistors shown in resistor region 126 in FIG. 2 is shown at 126 in FIG. 3. The resistance x is lower if the metal layer 108 is included in the gate material stack, and the resistance is higher, e.g., greater than about 5×, if the metal layer 108 is removed. As an example, the resistance was found to be about 150 Ohms/square if the metal layer 108 was included in the gate material stack in resistor region 124, and the resistance was found to be about 850 Ohms/square if the metal layer 108 was removed in the resistor region 126. Thus, a higher resistance resistor may be manufactured by removing the metal layer 108, although additional manufacturing process steps are required.

Thus, what are needed in the art are improved, cost-effective methods of fabricating resistors having a high resistance value in semiconductor devices that do not require additional manufacturing processes or steps.

Embodiments of the present invention achieve technical advantages by providing novel methods of forming resistors that do not require an additional mask level for the fabrication processes. Existing mask levels may be modified that result in either masking a resistor region during implantation processes, or exposing the resistor region during implantation processes used to form other portions of components such as source and drain regions of transistors of the semiconductor devices.

FIG. 4 is a cross-sectional view of a semiconductor device 130 in accordance with an embodiment of the present invention, wherein doping levels of a semiconductive material 140 of a resistor in a resistor region 132 are selected to increase the resistance value of the resistor. The semiconductive material 140 is either undoped or is doped differently than a semiconductive material 110 of a transistor in another region, e.g., in transistor region 122. At least one substance is implanted into the semiconductive material 110 of the gate of the transistor in the transistor region 122 or into the semiconductive material 140 of the resistor in the resistor region 132, so that the semiconductive material 110 and 140 is different for the gate of the transistor and the resistor, respectively. Three methods of forming differently doped semiconductive materials 110 and 140 for the gate of the transistor in region 122 and for resistor in region 132 will be described herein.

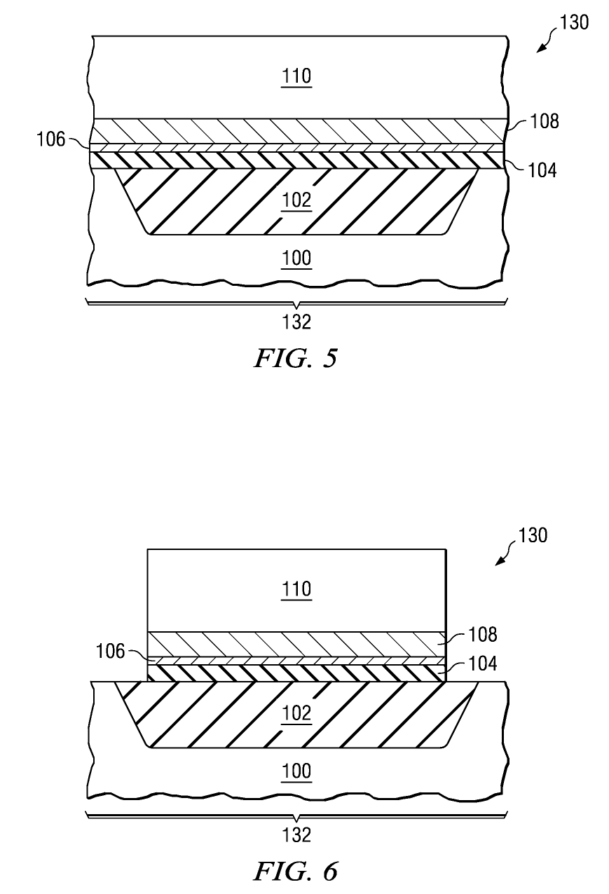

FIGS. 5 through 7 show cross-sectional views of a method of manufacturing a semiconductor device 130 in accordance with an embodiment of the present invention. Referring to FIG. 5, to manufacture the semiconductor device 130, first, a workpiece 100 is provided. The workpiece 100 may comprise a semiconductor substrate comprising silicon, body, or wafer, for example. The workpiece 100 may include other active components or circuits formed within and/or over the workpiece 100, not shown. The workpiece 100 may comprise silicon oxide over single-crystal silicon, for example. The workpiece 100 may include other conductive layers or other semiconductor elements, e.g., transistors, diodes, etc., not shown. Compound semiconductors, GaAs, InP, Si/Ge, or SiC, as examples, may be used in place of silicon. The workpiece 100 may comprise a silicon-on-insulator (SOI) or a SiGe-on-insulator substrate, as examples.

Isolation regions 102 may be formed in the workpiece 100, as shown. The isolation regions 102 may comprise shallow trench isolation (STI) regions or other types of isolation regions such as deep trench (DT) isolation and/or field oxide (FOX) regions, for example. The isolation regions 102 may be formed by etching trenches in the workpiece 100 using lithography and filling the trenches with one or more insulating materials, for example.

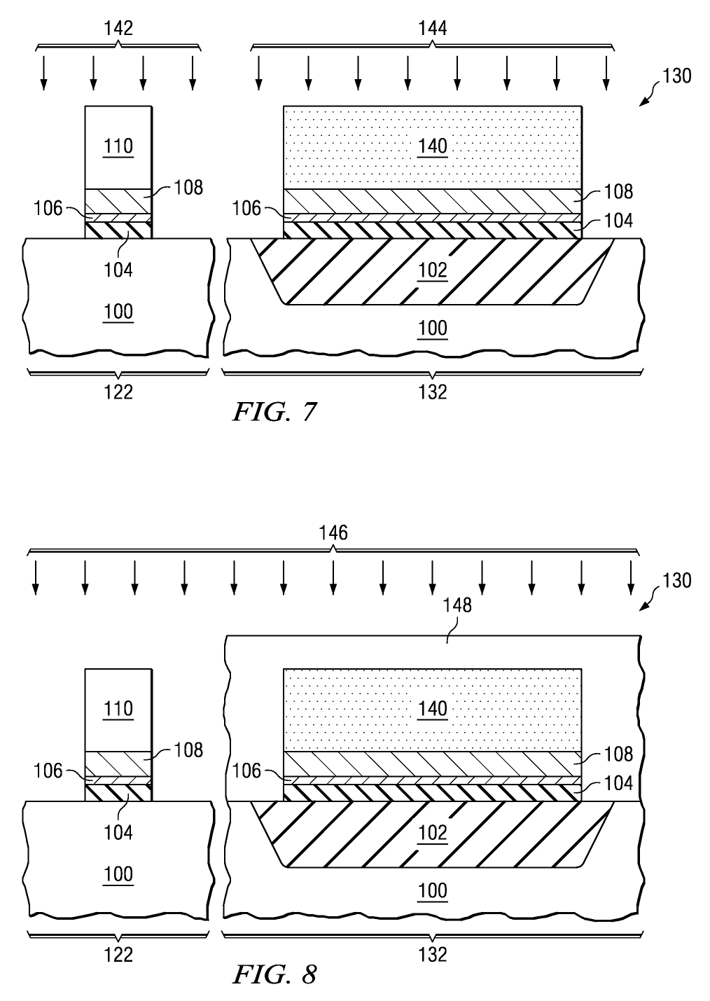

The workpiece 100 comprises a resistor region 132 and a transistor region 122, as shown in FIG. 7. The transistor region 122 is also referred to herein as a first region 122, and the resistor region 132 is also referred to herein as a second region 132, for example. The first region 122 comprises a region where at least one transistor will be formed. The second region 132 comprises a region where at least one resistor will be formed in accordance with an embodiment of the present invention.

In FIG. 7, only one transistor is shown in the first region 122, and only one resistor is shown in the second region 132; alternatively, a plurality of transistors may be formed in the first region 122, and a plurality of resistors may be formed in the second region 132, for example. Only one first region 122 and second region 132 are shown in the drawings; however, a plurality of first regions 122 and second regions 132 may be disposed across a surface of the workpiece 100, for example. One or more isolation regions, or portions of isolation regions 102, may be formed in the first region 122 and second region 132, for example. One or more isolation regions 102 may be formed between the first region 122 and the second region 132, not shown.

A gate dielectric material 104 is formed over the workpiece 100 and over the isolation region 102, as shown in FIG. 5. The gate dielectric material 104 may comprise about 0.5 to 5 nm of a dielectric material such as SiO₂, a nitride such as Si₃N₄, an oxynitride such as SiON, a high-k dielectric material having a dielectric constant or k value of greater than about 3.9, such as a hafnium-based dielectric or other high k materials, or combinations and/or multiple layers thereof, as examples. Alternatively, the gate dielectric material 104 may comprise other dimensions and materials, for example. The gate dielectric material 104 may be formed using an oxidation or nitridation process, chemical vapor deposition (CVD), atomic layer deposition (ALD), metal organic chemical vapor deposition (MOCVD), physical vapor deposition (PVD), a spin-on process, jet vapor deposition (JVD), or combinations thereof, as examples, although alternatively, other methods may also be used to form the gate dielectric material 104.

An optional cap layer 106 may be formed over the gate dielectric material 104, as shown in FIG. 5. The cap layer 106 may have a thickness of about 0.5 to 5 nm and may comprise LaO, DyO, MgO, or AlO, as examples. Alternatively, the cap layer 106 may comprise other materials and dimensions. The cap layer 106 may be used to pin the work function of the transistor in the transistor region 122, for example. The material and thickness of the cap layer 106 may be selected to achieve the desired work function for a transistor in the transistor region 122 that comprises a high-k gate dielectric material 104 and metal layer 108 in the gate 108/110, for example. The cap layer 106 may be different for p channel metal oxide semiconductor (PMOS) and n channel metal oxide semiconductor (NMOS) devices formed in the transistor region 122, for example. The cap layer 106 may be used to achieve a work function close to a band edge in some applications.

A metal layer 108 is formed over the cap layer 106, also shown in FIG. 5. The metal layer 108 may comprise about 3 to 30 nm of TiN, TaN, TiC, TiCN, MoN, other metals, or combinations and/or multiple layers thereof, as examples, although alternatively, the metal layer 108 may comprise other materials. The metal layer 108 may be formed by CVD, PVD, or other methods, as examples.

A semiconductive material 110 is formed or deposited over the metal layer 108. The semiconductive material 110 may comprise about 10 to 200 nm of a semiconductive material such as polysilicon or amorphous silicon, although alternatively, the semiconductive material 110 may comprise other dimensions and semiconductor materials. In some embodiments, the semiconductive material 110 comprises a thickness of about 50 nm, as an example. The semiconductive material 110 may be formed by CVD, PVD, or other methods, as examples.

The semiconductive material 110, metal layer 108, cap layer 106, and gate dielectric material 104 may comprise a gate stack for at least one transistor in a transistor region 122 (see FIG. 7) of the semiconductor device 130, for example. A resistor comprising the semiconductive material 110 and metal layer 108 will also be formed in the resistor region 132 from the gate stack for the transistor, in accordance with embodiments of the present invention. However, either the semiconductive material 110 in the resistor region 132 or the semiconductive material 110 in the transistor region 122 is altered in accordance with embodiments of the present invention, so that the semiconductive material 110 for the gate of transistors in the transistor region 122 is different than the semiconductive material 140 for resistors in the resistor region 132.

The gate stack material 104, 106, 108, and 110 is patterned, forming a gate of a transistor in the first region 122 of the workpiece 100 (see FIG. 7) and forming a resistor in the second region 132 of the workpiece 100, as shown in FIG. 6. The resistor is formed over the isolation region 102 and comprises the semiconductive material 110 and the metal layer 108. The gate dielectric material 104 provides isolation for the resistor from the underlying workpiece 100, for example. The type of material of the metal layer 108 and semiconductive material 110, the thickness of the metal layer 108 and semiconductive material 110, and the dimensions of the patterned metal layer 108 and semiconductive material 110 may be selected to achieve a desired amount of resistance for the resistor in the second region 132 and also to achieve desired properties for the transistor in the first region 122 of the workpiece 100, for example.

In some embodiments, the gate dielectric material 104 may be removed from the second region 132 of the workpiece 100, before forming the optional cap layer 106, or before forming the metal layer 108 over the isolation region 102 in the second region 132 of the workpiece 100, for example, not shown in the drawings. The resistor may be formed entirely over an isolation region 102 so that the gate dielectric material 104 is not required to isolate the resistor in the second region 132 from the workpiece 100.

The resistor in the second region 132 may comprise a length or dimension d₁ of about 1 μm or greater and a width or dimension d₂ of about 1 μm or greater, as shown in the top view in FIG. 14, as examples. The length d₁ and width d₂ of the resistor in the second region 132 are functions of the application and the desired amount of resistance for the resistor in the second region 132, for example. In some applications, the resistor in the second region 132 may comprise a length d₁ of about 5 μm and a width d₂ of about 1 to 2 μm, as one example. Alternatively, the resistor in the second region 132 of the workpiece 100 may comprise other dimensions.

The gate stack 104, 106, 108, and 110 may be patterned by depositing a layer of photosensitive material (not shown) over the semiconductive material 110, and patterning the layer of photosensitive material using a lithography process. Portions of the layer of photosensitive material are exposed to energy, e.g., using a lithography mask or a direct patterning method, exposing portions of the layer of photosensitive material. The layer of photosensitive material is developed, and portions of the layer of photosensitive material are then removed. The layer of photosensitive material is used as an etch mask while portions of the gate stack 104, 106, 108, and 110 are etched away using an etch process. The layer of photosensitive material is then removed. An optional hard mask (also not shown) may also be used in the lithography process to pattern the gate stack 104, 106, 108, and 110, for example.

The transistor in the first region 122 is exposed to a first process 142, and the resistor in the second region 132 is exposed to a second process 144, as shown in FIG. 7. The second process 144 is different than the first process 142, resulting in the semiconductive material 140 of the resistor in the second region 132 being different than the semiconductive material 110 of the gate of the transistor in the first region 122.

The first process 142 may comprise implanting a substance into the semiconductive material 110 of the gate of the transistor in the first region 122, and the second process 144 may comprise masking the semiconductive material of the resistor in the second region 132 during the first process 142, resulting in a resistor comprising a semiconductive material 140 that is different than the semiconductive material 110 of the gate of the transistor in the first region 122, in some embodiments.

In other embodiments, the first process 142 may comprise masking the semiconductive material 110 of the gate of the transistor in the first region 122 while the second process 144 is used to alter the semiconductive material 140 of the resistor in the second region 132. The second process 144 may comprise implanting at least one substance into the semiconductive material 140 of the resistor in the second region 132 in these embodiments, for example, to be described further herein.

Advantageously, masking the first region 122 or the second region 132 does not require an additional lithography mask in accordance with embodiments of the present invention; rather, masking the first region 122 or the second region 132 is implemented in existing masking levels of the semiconductor device 130.

FIG. 8 illustrates a method of forming a resistor in accordance with an embodiment of the present invention. In this embodiment, the resistor in the second region 132 of the workpiece 100 is masked using a layer of photosensitive material 148. The layer of photosensitive material 148 is deposited over the entire workpiece 100, and the layer of photosensitive material 148 is patterned using lithography to remove the photosensitive material 148 from over the transistor in the first region 122 of the workpiece 100. The patterning of the layer of photosensitive material 148 may be achieved using an existing lithography mask level for the semiconductor device 130, so that an additional lithography mask and lithography process are not required, for example. If the semiconductor device 130 includes PMOS and NMOS devices, and the transistor in the first region 122 comprises a PMOS device, the patterning of the layer of photosensitive material 148 may be accomplished using a mask level used to protect the NMOS devices during an implantation process for the transistor gates of the PMOS devices, for example.

An implantation process 146 is then used to implant a dopant material into the semiconductive material 110 of the gate of the transistor in the first region 122 of the workpiece 100, as shown in FIG. 8. The dopant material may comprise a P+ material such as boron or an N+ material such as phosphorus, as examples. Alternatively, the dopant material may comprise other materials. The layer of photosensitive material 148 is then removed.

Thus, the semiconductive material 140 of the resistor in the second region 132 comprises a different material than the semiconductive material 110 of the gate of the transistor in the first region 122. The semiconductive material 140 comprises undoped polysilicon or amorphous silicon, and the semiconductive material 110 of the gate of the transistor in the first region 122 comprises polysilicon or amorphous silicon doped with a P+ dopant material. Alternatively, the semiconductive material 110 of the gate of the transistor in the first region 122 may be doped with an N+ dopant material, for example.

The undoped semiconductive material 140 of the resistor in the second region 132 has a higher resistance value than a resistance of the semiconductive material 110 of the gate of the transistor formed in the first region 122, advantageously. The combination of the undoped semiconductive material 140 with the metal layer 108 results in a higher resistance for the resistor in the second region 132 relative to the resistance of the semiconductive material 110 of the gate of the transistor in the first region 122, for example.

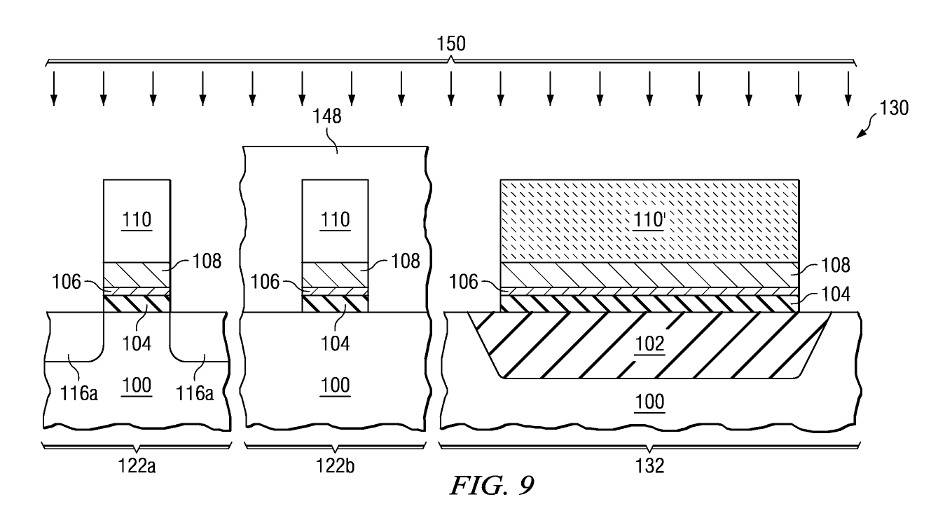

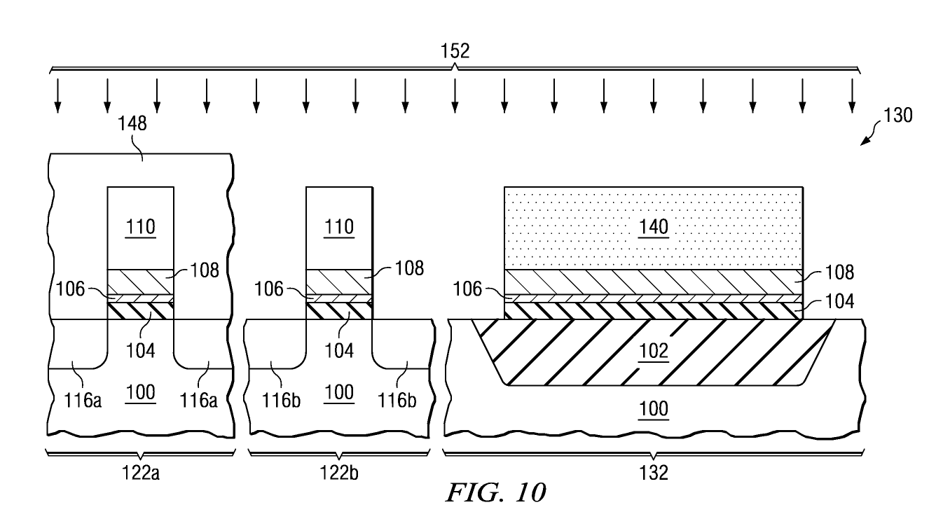

FIGS. 9 and 10 illustrate a method of forming a resistor in accordance with another embodiment of the present invention. In this embodiment, the first region 122 of the workpiece 100 (see FIG. 7) comprises a region 122a of first transistors and a region 122b of second transistors. The region 122a of first transistors may comprise a region 122a of PMOS devices and the region 122b of second transistors may comprise a region 122b of NMOS devices, for example. Source and drain regions of the first transistors and the second transistors in regions 122a and 122b, respectively, may require different types of doping. The semiconductive material 110 of the resistor in the second region 132 of the workpiece 100 is doped with a first dopant material used to form a source or drain region of first transistors in region 122a of the first region, and the semiconductive material 110 of the resistor in the second region 132 of the workpiece 100 is also doped with a second dopant material used to form a source or drain region of second transistors in region 122b of the first region 122.

For example, in FIG. 9, region 122b comprising the second transistors is masked using a first layer of photosensitive material 148, and source and drain regions 116a of the first transistors in region 122a are formed by implanting a first dopant material into the workpiece 100 using a first implantation process 150. The first dopant material is also implanted into the semiconductive material 110 of the resistor in the second region 132 of the workpiece 100, forming a semiconductive material 110′ that is implanted with the first dopant material, as shown in FIG. 9. The first dopant material may comprise a P+ material, for example.

The semiconductive material 110 of the first transistors in region 122a may optionally also be masked with the layer of photosensitive material 148 during the first implantation process 150, not shown. Alternatively, the semiconductive material 110 of the first transistors in region 122a may be implanted with a different type of dopant or different concentration of dopant, before or after the first implantation process 150, also not shown.

Then, shown in FIG. 10, region 122a comprising the first transistors is masked using a second layer of photosensitive material 148, and source and drain regions 116b of the second transistors in region 122b are formed by implanting a second dopant material into the workpiece 100 using a second implantation process 152. The second dopant material is also implanted into the semiconductive material 110′ of the resistor in the second region 132 of the workpiece 100, forming semiconductive material 140 that is implanted with both the first dopant material and the second dopant material, as shown in FIG. 10. The second dopant material may comprise an N+ material, for example.

The semiconductive material 110 of the second transistors in region 122b may optionally also be masked with the layer of photosensitive material 148 during the second implantation process 152, not shown. Alternatively, the semiconductive material 110 of the second transistors in region 122b may be implanted with a different type of dopant or a different concentration of dopant, before or after the first implantation process 150 and/or second implantation process 152, also not shown.

Thus, in the embodiment shown in FIGS. 9 and 10, the semiconductive material 140 of the resistor in the second region 132 is implanted with two different dopant materials, both P+ and N+, achieving a resistor having a higher resistance value than a resistance of the semiconductive material 110 of gates of the transistors in regions 122a and 122b of the first region 122 of the workpiece 100. Advantageously, no additional lithography masks are required to achieve the higher resistance resistor in the second region 132 of the workpiece 100. For example, a mask level used to mask transistors in regions 122a and 122b may be altered to open or expose the layer of photosensitive material 148 over the second region 132 of the workpiece 100 during the implantation processes 150 and 152.

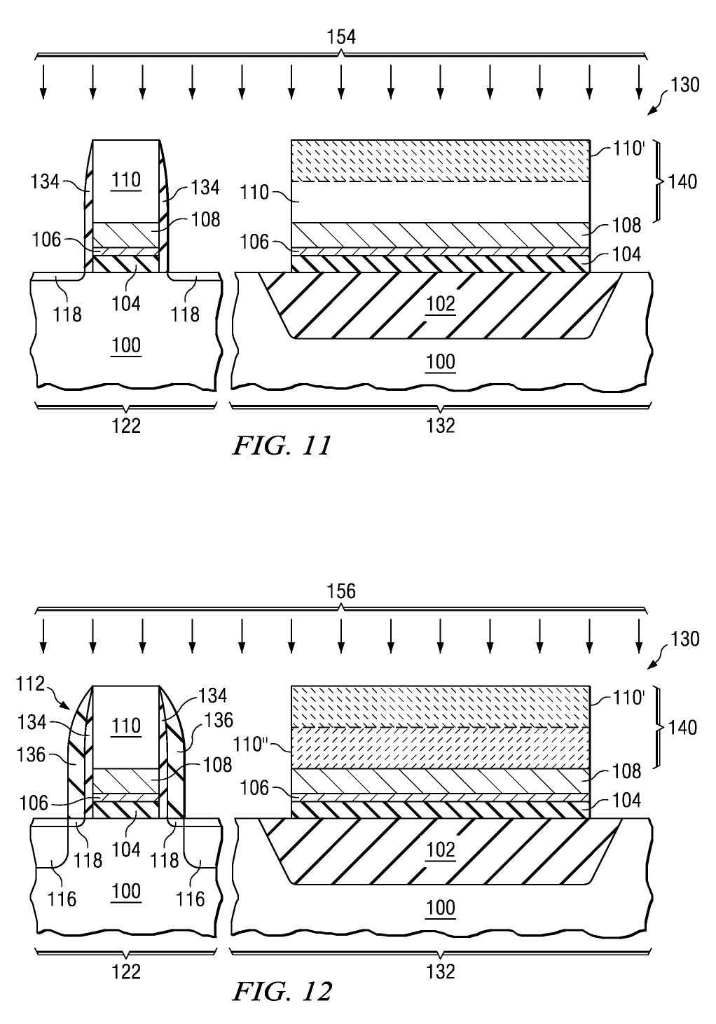

FIGS. 11 and 12 illustrate a method of forming a resistor in accordance with yet another embodiment of the present invention. In this embodiment, two implantation processes 154 and 156 are also used to alter the semiconductive material 140 of the resistor in the second region 132 of the workpiece 100, relative to the semiconductive material 110 of the gate of the transistor in the first region 122 of the workpiece 100.

One implantation process 154 comprises a shallow implantation of a first dopant material that is used to form extension implantation regions 118 of source and drain regions of the transistor in the first region 122, as shown in FIG. 11. The implantation process 154 results in a shallow implantation of the first dopant material into a top portion of the semiconductive material 110 of the resistor in the workpiece 100, as shown in FIG. 11 at 110′. The other implantation process 156 comprises a deeper implantation process that is used to form a halo implantation region 116 of source and drain regions of the transistor in the first region 122 of the workpiece 100, as shown in FIG. 12. The implantation process 156 results in a deep implantation of the second dopant material into a lower portion of the semiconductive material 110 of the resistor in the workpiece 100, as shown in FIG. 12 at 110″.

In some embodiments, the implantation process 154 comprises a shallow boron implant at a high dose, e.g., at a dose in the order of about 1×10¹⁵, and the implantation process 156 comprises a deeper arsenic halo implant, for example. Alternatively, the implantation processes 154 and 156 may comprise other dopant types and concentrations.

Sidewall spacers 112 may comprise two spacer materials 134 and 136 comprising insulating materials that are formed over the gate stack 104, 106, 108, 110 sidewalls before the implantation processes 154 and 156, respectively. A masking material may be formed over the top surface of the semiconductive material 110 of the gate of the transistor in the first region 122, to prevent the gate from being implanted with the dopant materials of the first and second implantation processes 154 and 156, for example, not shown. Or, alternatively, the semiconductive material 110 of the gate of the transistor in region 122 may be implanted with a different type of dopant or a different concentration of dopant, before or after the first implantation process 154 and/or the second implantation process 156, not shown. The dopant materials of the first implantation process 154 and the second implantation process 156 may comprise different types of dopant materials and/or may comprise a different concentration of a single dopant material, for example.

Thus, in the embodiment shown in FIGS. 11 and 12, the semiconductive material 140 of the resistor in the second region 132 is implanted with two different dopant implantation processes 154 and 156, achieving a resistor having a higher resistance value than a resistance of the semiconductive material 110 of gates of the transistor in the first region 122 of the workpiece 100. The metal layer 108 of the resistor in the second region 132 is electrically separated by a layer of semiconductive material 140 having a very high resistance due to the two dopant implantation processes 154 and 156. The upper portion 110′ of the semiconductive material 140 is electrically separated from the metal layer 108 by the lower portion 110″ of the semiconductive material 140. The lower portion 110″ of the semiconductive material 140 functions as a depletion zone so that current flow in the resistor primarily occurs in the upper portion 110′ of the semiconductive material. Thus, the resistance of the resistor is increased.

Advantageously, as in the previous embodiments described herein, no additional lithography masks or processes are required to achieve the higher resistance resistor in the second region 132 of the workpiece 100. For example, if the semiconductor material 110 is required to be masked during the implantation processes 154 and 156, mask levels used to mask other regions of the workpiece 100 during the implantation processes 154 and 156 may be altered to cover the semiconductive material 110 of gates of the transistor in the first region 122 of the workpiece 100 with a photosensitive masking material during the implantation processes 154 and 156. The same mask levels may also be altered to uncover or expose the second region 132 so the semiconductive material 140 is altered.

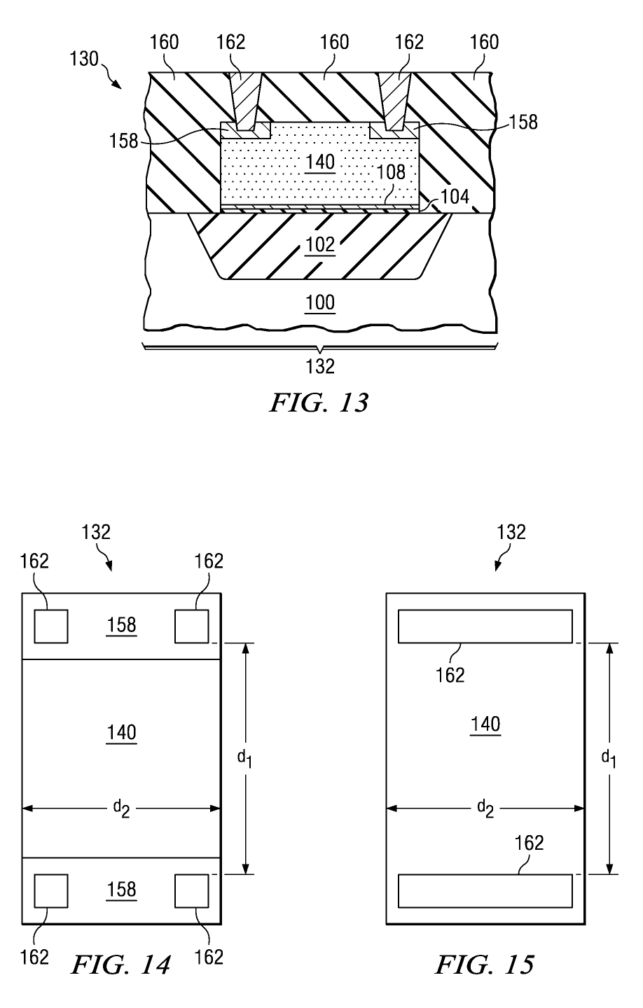

Ends of the resistor in the second region 132 may optionally be silicided, and contacts 162 may be coupled to the silicided ends of the resistor. For example, FIG. 13 shows a cross-sectional view of a resistor in a second region 132 of a workpiece 100 in accordance with an embodiment of the present invention after contacts 162 have been coupled to each end of the resistor. The optional cap layer 106 is not included in the embodiment shown in FIG. 13, for example. The resistor in the second region 132 includes the metal layer 108 and the semiconductive material 140 that is either undoped or that is doped differently than a semiconductive material 110 of gates of the transistor in the first region 122 (see FIG. 7), for example. The silicide 158 may be formed over a first end of the resistor and over a second end of the resistor opposite the first end, as shown. The silicide 158 may lower the contact resistance in some applications, for example. The silicide 158 may be used to define a linear ohmic contact resistance of the resistor in the second region 132 and may avoid Schottky diode behavior of portions of the resistor, for example.

The contacts 162 may be formed using a single damascene process, e.g., by forming an insulating material 160 over the workpiece 100 and the resistor comprising the semiconductive material 140 and the metal layer 108. The insulating material 160 is patterned using lithography, and the patterned insulating material 160 is filled with a conductive material to form the contacts 162. Excess conductive material is then removed from over the insulating material 160 using an etch process and/or a chemical mechanical polishing (CMP) process, for example. Alternatively, the contacts 162 may be formed using a subtractive etch process of a conductive material formed over the resistor, and the insulating material 160 may be formed over the contacts 162 and resistor 140/108.

The contacts 162 may comprise a plurality of contacts coupled to silicided ends of the resistor in the second region 132, as shown in a top view in FIG. 14. Only two contacts 162 are shown coupled to each end of the resistor in FIG. 14; alternatively, a plurality of contacts may be coupled to the ends of the resistor, for example, not shown.

Alternatively, the contacts 162 may comprise elongated contact bars, as shown in a top view in FIG. 15. If elongated contact bars 162 are used as shown in FIG. 15, the silicide 158 may be omitted in some applications. Elongated contact bars 162 have a lower contact resistance and may not require the silicide 158 to reduce the contact resistance in some applications, for example. A lower end resistance (Rend) of the resistor may be achieved by eliminating the silicide 158 and using elongated contact bars 162, for example, by eliminating tungsten-silicide and silicide-polysilicon transition resistances.

In other applications, the silicide 158 may be included if elongated contact bars 162 are used. The silicide 158 may function as an etch stop during an etch process of the contact 162, for example, providing a higher etch selectivity than the semiconductive material 140. The elongated contact bars improve the contact resistance because of the larger contact area provided.

Note that silicide regions are often formed in other regions of semiconductor devices, such as over gates, sources and drains of transistors. Thus, no additional lithography masks are required to form the optional silicide 158 regions of the semiconductor devices 130 described herein. The silicide 158 may be formed over the ends of the resistors in the second region 132 during the formation of other silicided regions of the semiconductor devices 130, for example. The silicide 158 may comprise NiSi or other types of silicide, for example.

Sidewall spacers 112 may also be formed on sidewalls of the resistors in the second region 132, for example (see FIG. 4). The sidewall spacers 112 may be formed at the same time and using the same materials as sidewall spacers 112 of the transistors formed in the first region 122, for example, as described with reference to FIGS. 11 and 12.

Additional insulating material layers and conductive material layers, e.g., metallization layers (not shown), may be formed over the novel resistors in second regions 132 described herein, and may be used to interconnect the various components of the semiconductor device 130.

Embodiments of the present invention achieve technical advantages by forming resistors 140/108 using gate material layers of transistor devices of semiconductor devices 130. Embodiments of the present invention include methods of fabricating the semiconductor devices 130 and resistors in the second regions 132 described herein during the fabrication processes for transistors in the first regions 122 of the semiconductor devices 130, for example. Embodiments of the present invention also include semiconductor devices 130 and resistors manufactured using the methods described herein.

Embodiments of the present invention are particularly useful when implemented in resistors for radio frequency (RF) circuits and applications. Embodiments of the invention may also be implemented in other semiconductor applications such as analog circuits, mixed signal circuits, and other applications requiring relatively large resistors requiring a high resistance, for example. Embodiments of the present invention may also be implemented in other types of circuits and semiconductor devices.

The novel resistors in the second regions 132 advantageously may be formed during the fabrication and lithography processes used to form other devices such as transistors of the semiconductor devices 130, and thus do not require any additional processing steps, lithography masks, or manufacturing costs. Additional etch processes and lithography processes are not required to manufacture the novel resistors in accordance with embodiments of the present invention. The masking and implantation processes described herein may be included in existing mask levels for the semiconductor device 130.

Although embodiments of the present invention and their advantages have been described in detail, it should be understood that various changes, substitutions and alterations can be made herein without departing from the spirit and scope of the invention as defined by the appended claims. For example, it will be readily understood by those skilled in the art that many of the features, functions, processes, and materials described herein may be varied while remaining within the scope of the present invention. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method of fabricating a resistor, the method comprising:
forming a semiconductive material over a workpiece;
patterning at least the semiconductive material, forming a gate of a transistor in a first region of the workpiece and forming a resistor in a second region of the workpiece; and
implanting at least one substance into the semiconductive material of the gate of the transistor or the resistor so that the semiconductive material is different for the gate of the transistor and the resistor.

2. The method according to claim 1, wherein implanting the at least one substance into the semiconductive material of the gate of the transistor or the resistor comprises masking the resistor in the second region of the workpiece, and implanting a dopant material into the semiconductive material of the gate of the transistor in the first region of the workpiece.

3. The method according to claim 1, wherein patterning the at least the semiconductive material comprises forming a first transistor and forming a second transistor in the first region of the workpiece, wherein implanting the at least one substance into the semiconductive material of the gate of the transistor or the resistor comprises:
implanting the semiconductive material of the resistor in the second region of the workpiece with a first dopant material used to form a source region or drain region of the first transistor in the first region of the workpiece; and
implanting the semiconductive material of the resistor in the second region of the workpiece with a second dopant material used to form a source region or drain region of the second transistor in the first region of the workpiece.

4. The method according to claim 1, wherein implanting the at least one substance into the semiconductive material of the gate of the transistor or the resistor comprises:
implanting the semiconductive material of the resistor in the second region of the workpiece with a first dopant material used to form an extension implantation region of the transistor in the first region of the workpiece; and
implanting the semiconductive material of the resistor in the second region of the workpiece with a second dopant material used to form a halo implantation region of the transistor in the first region of the workpiece.

5. The method according to claim 1, wherein implanting the at least one substance into the semiconductive material of the transistor or the resistor results in an increased resistance of the resistor in the second region of the workpiece relative to a resistance of the gate of the transistor in the first region of the workpiece.

6. The method according to claim 1, wherein forming the resistor in the second region of the workpiece comprises forming a resistor comprising a first end and a second end opposite the first end, further comprising siliciding a top surface of the first end and the second end of the resistor, and coupling at least one first contact to the first end or coupling at least one second contact to the second end of the resistor.

7. The method according to claim 1, wherein forming the resistor in the second region of the workpiece comprises forming a resistor comprising a first end and a second end opposite the first end, further comprising coupling a first elongated contact bar to the first end or coupling a second elongated contact bar to the second end of the resistor.

8. A resistor manufactured in accordance with the method of claim 1.

9. A method of fabricating a semiconductor device, the method comprising:
forming a gate dielectric material over a workpiece;
forming a metal layer over the gate dielectric material;
forming a semiconductive material over the metal layer;
patterning the semiconductive material, the metal layer, and the gate dielectric material, forming a gate of at least one transistor in a first region of the workpiece and forming at least one resistor in a second region of the workpiece; and
implanting at least one substance into the semiconductive material of the gate of the at least one transistor or the at least one resistor so that the semiconductive material is different for the gate of the at least one transistor and the at least one resistor.

10. The method according to claim 9, wherein implanting the at least one substance into the semiconductive material of the gate of the at least one transistor or the at least one resistor comprises implanting a P+ or an N+ material into the semiconductive material of the gate of the at least one transistor in the first region of the workpiece.

11. The method according to claim 9, wherein implanting the at least one substance into the semiconductive material of the gate of the at least one transistor or the at least one resistor comprises implanting a P+ type material and an N+ type material into the semiconductive material of the at least one resistor in the second region of the workpiece.

12. The method according to claim 9, wherein implanting the at least one substance does not comprise implanting the at least one substance into the semiconductive material of the at least one resistor in the second region of the workpiece.

13. The method according to claim 9, wherein implanting the at least one substance into the semiconductive material of the gate of the at least one transistor or the at least one resistor comprises:
implanting the semiconductive material of the at least one resistor in the second region of the workpiece with a first implantation process; and
implanting the semiconductive material of the at least one resistor with a second implantation process, the second implantation process comprising a deeper implantation process than the first implantation process.

14. The method according to claim 9, wherein implanting the at least one substance into the semiconductive material of the gate of the at least one transistor or the at least one resistor comprises implanting the at least one substance into the semiconductive material of the at least one resistor in the second region of the workpiece during an implantation process for the fabrication of the at least one transistor in the first region of the workpiece.

15. The method according to claim 9, wherein implanting the at least one substance into the semiconductive material of the gate of the at least one transistor or the at least one resistor comprises covering the at least one resistor or exposing the at least one resistor during an implantation process for the semiconductor device using an existing lithography masking level for the semiconductor device.

16. A semiconductor device, comprising:
a transistor disposed in a first region of a workpiece, the transistor including a gate comprising a semiconductive material; and
a resistor disposed in a second region of the workpiece, the resistor comprising the semiconductive material, wherein the semiconductive material of the resistor in the second region of the workpiece is implanted with a different substance than the semiconductive material of the transistor in the first region of the workpiece is implanted with, or wherein the semiconductive material of the transistor in the first region of the workpiece is implanted with a substance and the semiconductive material of the resistor in the second region of the workpiece is not implanted with the substance.

17. The semiconductor device according to claim 16, wherein the transistor and the resistor comprise a metal layer disposed beneath the semiconductive material and a gate dielectric material disposed beneath the metal layer.

18. The semiconductor device according to claim 17, wherein the gate dielectric material comprises about 0.5 to 5 nm of SiO₂, Si₃N₄, SiON, a high-k dielectric material having a dielectric constant (k) of greater than about 3.9, or combinations and/or multiple layers thereof.

19. The semiconductor device according to claim 17, wherein the metal layer comprises about 3 to 30 nm of TiN, TaN, TiC, TiCN, MoN, other metals, or combinations and/or multiple layers thereof.

20. The semiconductor device according to claim 17, further comprising a cap layer disposed between the gate dielectric material and the metal layer.

21. The semiconductor device according to claim 16, wherein the semiconductive material comprises about 10 to 200 nm of polysilicon or amorphous silicon.

22. The semiconductor device according to claim 16, wherein the resistor is implemented in a radio frequency (RF) circuit, an analog circuit, or a mixed signal circuit.
